(19) United States
(12) Patent Application Publication
(10) Pub. No.: US 2020/0334400 A1
(43) Pub. Date: Oct. 22, 2020

(54) METHOD AND APPARATUS FOR SETTING THERMAL COMFORT SCALE OF AGE-SPECIFIC PERCEIVED TEMPERATURE OF RESIDENTS BASED ON THERMAL STRESS EXPERIMENT IN ARTIFICIAL CLIMATE CHAMBER

(71) Applicant: NATIONAL INSTITUTE OF METEOROLOGICAL SCIENCES, Seogwipo-si (KR)

(72) Inventors: MiSun KANG, Seogwipo-si (KR); Kyu Rang KIM, Icheon-si (KR); Changbum CHO, Seoul (KR); Ji-Sun LEE, Seogwipo-si (KR); Jong-Chul HA, Seogwipo-si (KR); Joo-Young LEE, Seoul (KR)

(21) Appl. No.: 16/849,299

(22) Filed: Apr. 15, 2020

(30) Foreign Application Priority Data
Apr. 16, 2019 (KR) 10-2019-0044286

(51) Int. Cl. G06F 30/20; G06N 5/02

(52) U.S. Cl. CPC G06F 30/20; G06N 5/02

(57) ABSTRACT

Provided is a method for setting a thermal comfort scale of an age-specific perceived temperature of residents living in a certain area based on an experiment exposed to thermal stress environment in an artificial climate chamber. The method includes: setting an experimental condition of the experiment exposed to thermal stress environment; surveying an age-specific thermal sensation vote according to the experimental condition of the experiment; simulating a predicted mean vote and an age-specific perceived temperature by use of a Klima-Michel model according to measuring elements of the experiment; predicting an age-specific thermal sensation vote according to variations in perceived temperature on the basis of the survey results of the age-specific thermal sensation vote according to measuring factors of the environment exposed to the age-specific thermal stress environments and the age-specific perceived temperature; and setting a danger standard or comfort scale of the age-specific perceived temperature of the residents living.

### BACKGROUND OF THE INVENTION

### Field of the Invention

The present invention relates to a technology for setting a thermal comfort scale of an age-specific perceived temperature (PT), and more particularly, to a method and apparatus for setting a thermal comfort scale of an age-specific perceived temperature of residents, based on thermal sensation vote (TSV) according to results of experiment exposed to thermal stress environment which is conducted for young subjects and old subjects, and the perceived temperature calculated by human heat production of the subjects and environmental conditions of experiment.

### Background of the Related Art

In order to accurately simulate thermal stress on a human body which is caused by the intense heat, it is important to consider human thermal balance that explains effects of thermal environments on the human body, in view of weather parameters, behavior characteristics (e.g., activity and clothing), and physical measurements.

The Perceived Temperature (PT; ° C.) is one of the human heat balance model and is based on a complete heat budget model (also referred to as Klima-Michel Model) developed by Deutscher Wetterdienst. The Perceived Temperature is defined as an air temperature of a reference environment in which the thermal perception would be the same as under the actual environment. The Perceived Temperature and its thermal comfort range (very hot; PT≤38° C., neutral or comfortable; 0≤PT<20° C., and very cold; PT≥39° C.) are based on the Predicted Mean Vote (PMV) proposed by Fanger et al (1970) (refer to thermal sensation scales used by ASHRAE (2001) and VDI (2008)) and applied the comfort equation of Gagge et al. (1986) for warm and humid condition. The perceived temperature (PT) is calculated for a reference subject with an internal heat production of 135 W/m² who is walking at 4 km/h on flat ground.

The predicted mean vote (PMV) was developed from data obtained from studies which were performed by a group of participants who are living in Western Europe and North America. However, the thermal comfort scale calculated by the actual thermal sensation vote (TSV) should be reflected by subjective deviations according to expectations for experiences on regional weather, social culture, economy, age, and recent outdoor surroundings.

In particular, it is known that even though the intense heat of the same intensity occurs, the thermal stress or thermal comfort scale felt by people and thus thermal morbidity and mortality caused by the thermal stress differ from individual to individual according to age, and heat-wave vulnerability is remarkably high in the elderly group.

Therefore, in order to properly utilize the perceived temperature developed in Germany according to inherent region weather, the thermal comfort scale for the perceived temperature (PT) should be defined for every resident according to age and country. For example, it is necessary to newly define the thermal comfort scale for Korean residents in order to apply the perceived temperature to Korean weather.

### SUMMARY OF THE INVENTION

Therefore, the present invention has been made in view of the above problems in the related art, and one object of the present invention is to provide a method and apparatus for setting a thermal comfort scale of a perceived temperature (PT) by age of certain residents (i.e., a perceived temperature model suitable for residents of interest) based on thermal stress experiment carried out in an artificial climate chamber, by which the experiment exposed to the thermal stress environment (hot environment and exercise loading conditions) in the artificial climate chamber is carried out for residents living in a certain area, and a thermal comfort scale of the perceived temperature (PT) by age (young group and elderly group) which is suitable for the residents living in the certain area is set by use of results of thermal sensation vote (TSV) by age and the perceived temperature under hot environments and exercise loading conditions, thereby providing a model of the perceived temperature suitable for the residents living in the area of interest.

According to one aspect of the present invention, there is provided a method for setting a thermal comfort scale of an age-specific perceived temperature of residents living in a certain area based on an experiment exposed to thermal stress environment in an artificial climate chamber, the method comprising: a step of setting an experimental condition of the experiment exposed to thermal stress environment; a step of surveying an age-specific thermal sensation vote according to the experimental condition of the experiment exposed to thermal stress environment; a step of simulating a predicted mean vote and an age-specific perceived temperature by use of a Klima-Michel model according to measuring elements of the experiment exposed to thermal stress environment; a step of predicting an age-specific thermal sensation vote according to variations in perceived temperature on the basis of the survey results of the age-specific thermal sensation vote according to measuring factors of the environment exposed to the age-specific thermal stress environments and the age-specific perceived temperature; and a step of setting a danger standard or comfort scale of the age-specific perceived temperature of the residents living in a certain.

The experimental condition includes an experiment time, an experiment location, an experiment group, an experiment hour, information on a subject's body belonging to the experiment group, a heat insulating value of clothing, an environmental condition and an exercise loading condition.

The environmental condition includes a temperature, a relative humidity and a wind speed.

The step of predicting the age-specific thermal sensation vote calculates a linear regression model for results of the thermal sensation vote to variations in the perceived temperature, in which a young group is applied to Equation 1 below, while an elderly group is applied to Equation 2 below:

TSV=0.13×PT−2.03 (Equation 1)

TSV=0.06×PT+1.06 (Equation 2).

### BRIEF DESCRIPTION OF THE DRAWINGS

FIG. 1 is a view illustrating an apparatus for setting a thermal comfort scale of a perceived temperature for a resident living in a certain area according to one embodiment of the present invention.

FIG. 2 is a flow chart illustrating a method for setting the thermal comfort scale of the perceived temperature for the resident living in a certain area by the apparatus in FIG. 1.

FIG. 3 is a view illustrating information on subject's body and experimental conditions exposed to thermal stress environments according to one embodiment of the present invention.

FIG. 4 is a view illustrating a process of carrying out the experiment exposed to the thermal stress environments and measuring factors according to one embodiment of the present invention.

FIG. 5 is a graph illustrating a relation between an age-specific perceived temperature of residents living in a certain area and a thermal sensation vote (predicted mean vote) according to one embodiment of the present invention.

FIG. 6 is a view illustrating the thermal sensation vote based on the thermal stress experiment according to one embodiment of the present invention and a thermal comfort scale of the perceived temperature for a young group and an elderly group of residents living in a certain area according to thermal stress intensity corresponding to the thermal sensation vote.

FIG. 7 is a block diagram illustrating an apparatus for setting a thermal comfort scale of a perceived temperature for residents living in a certain area according to another embodiment of the present invention.

### DETAILED DESCRIPTION OF THE PREFERRED EMBODIMENT

Preferred embodiments of the invention will be hereafter described with reference to the accompanying drawings.

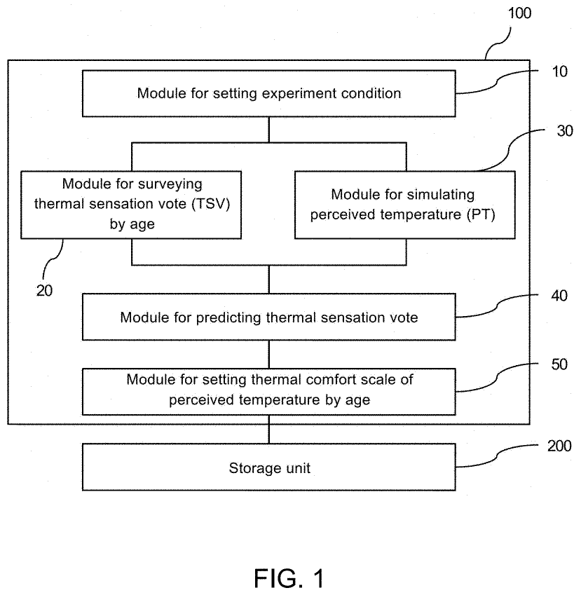

FIG. 1 is a view illustrating the configuration of a system for setting a thermal comfort scale of a perceived temperature for residents according to one embodiment of the present invention.

The system configured to realize the method for setting the thermal comfort scale of an age-specific perceived temperature of residents living in a certain area according to one embodiment of the present invention stands on the basis of an experiment exposed to thermal stress environment of an artificial climate chamber, and, as illustrated in FIG. 1, includes a module 10 for setting experimental condition, a module 20 for surveying a thermal sensation vote by age, a module 30 for simulating (calculating) a perceived temperature, a module 40 for predicting a thermal sensation vote, and a module 50 for setting a thermal comfort scale of a perceived temperature by age.

These modules 10 to 50 may be provided in a storage unit 200 to perform a series of predetermined processes according to operation of a control unit 100 connected to the storage unit 200, thereby realizing the method for setting the thermal comfort scale of the age-specific perceived temperature.

The control unit 100 may include a microprocessor, a central processor, and a micro controller, and the storage unit 200 may be provided with at least program or software module corresponding to these modules. The storage module 200 may include a semiconductor memory, a hard disc, and an optical disc.

The components of the apparatus for setting the thermal comfort scale of the age-specific perceived temperature of residents living in a certain area will now be described in more detail.

First of all, the module 10 for setting an experimental condition is one for setting experimental conditions exposed to thermal stress environment. Herein, the experimental conditions may include at least one of an experiment time, an experiment location, selection of groups of subjects who are classified into a group of young adult males (referred to as a young group) and a group of elderly males (referred to as an elderly group), an experiment time (hour) required for observing a progress of experiment processes, information on subject's body belonging to the experiment group, a heat insulating value of clothing, environmental conditions and an exercise loading condition.

The module 20 for surveying a thermal sensation vote by age is one for performing age-specific thermal sensation vote through the experiment process according to the environmental conditions of the experiment exposed to the thermal stress environment, and then surveying the results of the thermal sensation vote.

The module 30 for simulating (calculating) a perceived temperature is one for simulating or calculating an age-specific predicted mean vote and an age-specific perceived temperature according to the above-described environmental conditions by use of a Klima-Michel model.

The module 40 for predicting a thermal sensation vote is one for predicting the age-specific thermal sensation vote according to the change in the perceived temperature on the basis of the environmental conditions of experiment, the results of the age-specific thermal sensation vote, and the survey results.

The module 50 for setting the thermal comfort scale of the age-specific perceived temperature is one for setting a danger standard (thermal comfort scale) of the perceived temperature corresponding to the thermal sensation vote (thermal stress intensity) according to age (young group and elderly group) of residents living in a certain area.

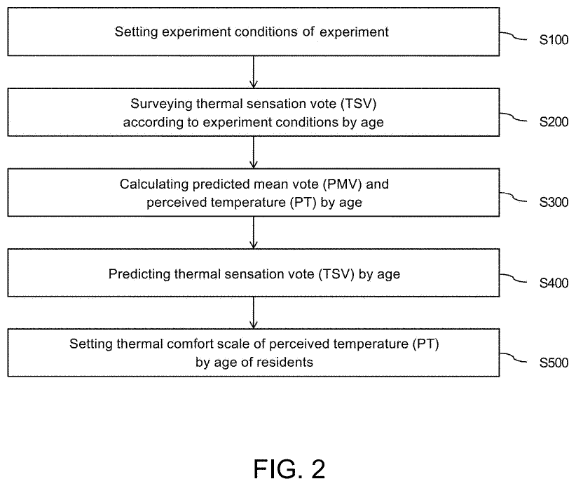

FIG. 2 is a flow chart illustrating the method for setting the thermal comfort scale of the perceived temperature for the residents according to one embodiment of the present invention. The method for setting the thermal comfort scale of the perceived temperature of the residents on the basis of the experiment by age exposed to the thermal stress environment in the artificial climate chamber according to one embodiment of the present invention will now be described in detail.

Referring to FIG. 2, the method of the present invention includes a step S100 of setting the experimental conditions, a step S200 of surveying the thermal sensation vote according to the experimental conditions by age, a step S300 of simulating or calculating the predicted mean vote and the age-specific perceived temperature by age, a step S400 of predicting the thermal sensation vote by age, and a step S500 of setting the danger standard (thermal comfort scale) of the perceived temperature by age of residents living in a certain area.

The step S100 of setting the experimental conditions may set at least one of an experiment time, an experiment location, selection of groups of subjects who are classified into a group of young adult males (referred to as a young group) and a group of elderly males (referred to as an elderly group), an experiment hour required for observing a progress of an experiment process, information on subject's body belonging to the experiment group, a heat insulating value of clothing, environmental conditions and an exercise loading condition.

The step S200 of surveying the thermal sensation vote according to the experimental conditions by age is a process of executing the thermal sensation vote according to the conditions of the experiment exposed to the thermal stress environment according to this embodiment. The results of the thermal sensation vote taken by subjects may be recorded by the age-specific thermal sensation vote surveying module 20.

Also, during the step S200 of surveying the thermal sensation vote according to the experimental conditions by age, measuring elements, such as a skin temperature, a rectal temperature, and a heart rate, of each resident can be continuously measured.

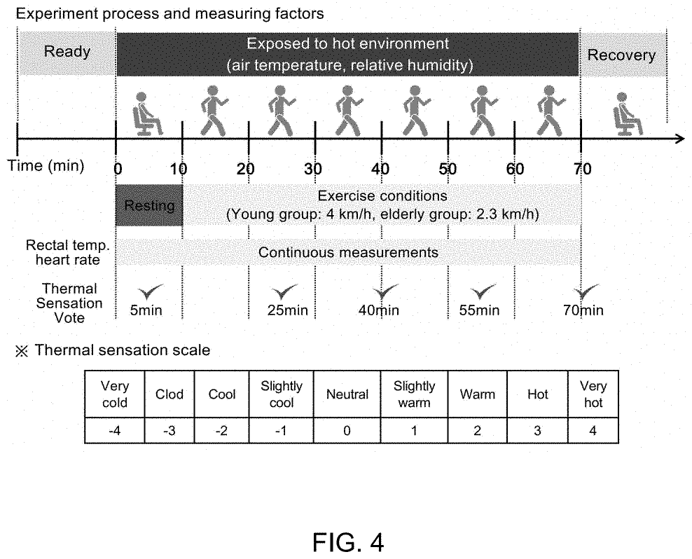

The step S300 of simulating or calculating the predicted mean vote and the perceived temperature by age is a step of simulating or calculating the predicted mean vote and the perceived temperature by age of each group by use of the Klima-Michel model which is reflected by the measuring factors of the experiment exposed to the thermal stress environment, as illustrated in FIG. 4.

The step S400 of predicting the thermal sensation vote by age is a step of predicting the thermal sensation vote (TSV) according to variations in perceived temperature by age on the basis of the survey results of the thermal sensation vote according to the perceived temperature and the environmental conditions which is obtained from the step S300 of simulating or calculating the predicted mean vote by age.

In other words, the step S400 of predicting the thermal sensation vote by age is to predict a linear regression model of the thermal sensation vote according to variations in perceived temperature. Specifically, in the step S400, the linear regression model is calculated by the relation between each environmental condition (PT 35 and 44r) and the age-specific thermal sensation vote surveyed under each environmental condition, and the thermal sensation for each perceived temperature is predicted by the linear regression model.

The step S500 of setting the thermal comfort scale of the perceived temperature by age of the residents is a step of setting the comfort scale of the perceived temperature for the thermal sensation vote according to age (young group and elderly group) of the residents living in a certain area or the thermal stress intensity on the basis of values derived by the step S400 of predicting the thermal sensation vote by age.

The respective steps S100 to S500 will now be described in more detail with reference to the accompanying drawings.

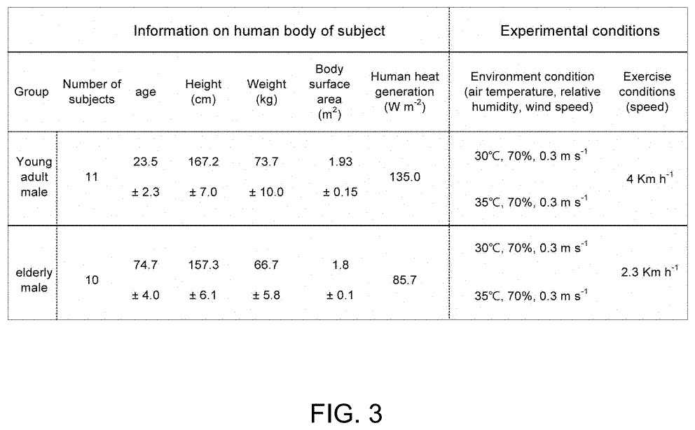

FIG. 3 is a view illustrating information on subject's body and the experimental conditions exposed to thermal stress environments according to one embodiment of the present invention. The experimental conditions according to one embodiment of the present invention will be illustrated.

The experiment time may be set as a period including a time when the thermal stress occurs at a certain area. For example, the experiment time may be set as a period corresponding to a summer season of a certain area (e.g., Korea) from June to August 2017.

The experiment location may be an artificial climate chamber located at a certain area. For example, the experiment location may be an artificial climate chamber operated by College of Human Ecology at Seoul National University.

The groups of subjects may be classified into a young group and an elderly group for the purpose of age-specific comparison. For example, the groups of subjects may be classified into a group of young adult males and a group of elderly males, or a group of young adult females and a group of elderly females. More specifically, the groups of subjects are 21 persons in total who are classified into 11 young adult males as a young group and 10 elderly males as an elderly group.

The experiment hour may be set as minutes to hours according to the experimental conditions. For example, the experiment hour may be set as 70 minutes in total. In this instance, the progress of the experiment process is observed while the subject takes a rest on a chair in the artificial climate chamber for 10 minutes, and then walks on a treadmill for 60 minutes.

The information on subject's body includes an age, a height, a weight, and a body surface area of individual resident belonging to the experiment group, and is determined in view of an average and a standard deviation. The information on subject's body may be stored in the storage unit or a database after some information is inputted or confirmed by a user through a user interface. At least some information on subject's body may be putted by a weighted value or a compensation value according to the average or standard deviation of the stored information of interest.

The heat insulating value of clothing is standardized by 0.4 to 0.5 clo (estimated insulating value) provided by the clothing of the subject. In this instance, a unit insulation value (1 clo) is defined by the insulation that will restrict heat loss to 1 kcal m⁻² h⁻¹ (through a body surface area of 1 m² for 1 hour) with a temperature gradient of 0.18° C. across a fabric. Herein, 1 clo corresponds to 0.18° C.·m²·h·kcal⁻¹ (0.155° C.·m²·W⁻¹).

The environmental conditions include a temperature, a relative humidity, and a wind speed, and may employ two environmental conditions to compare the thermal sensation vote by thermal stress level. For example, the first environmental conditions may be set by a temperature of 30° C., a relative humidity of 70%, and a wind speed of up to 0.3 ms⁻¹, while the second environmental conditions may be set by a temperature of 35° C., a relative humidity of 70%, and a wind speed of up to 0.3 ms⁻¹. The exercise loading condition may be set for the young group and the elderly group, respectively, in which the exercise loading condition for the young group may be set by a speed of 4.0 km h⁻¹ which is identical to the PT model of Germany. Also, the elderly group may be set by a walking speed of 2.3 km h⁻¹ based upon a reduction (60% relative to the young group) in the maximum oxygen consumption which is caused by graying. The exercise loading condition may be properly adjusted within a range of about ±10 depending upon the experiment area or the experiment time.

FIG. 4 is a view illustrating the process of carrying out the experiment exposed to the thermal stress environments and measuring factors according to one embodiment of the present invention.

In this embodiment, the survey for the results of the thermal sensation vote for the subjects are carried out by age under the environmental conditions, respectively. The experiment process is carried out while the subject takes a rest on a chair in the artificial climate chamber for 10 minutes, and then walks on a treadmill for 60 minutes according to the exercise loading conditions. In this instance, the thermal sensation voted are performed at an elapse of 5 minutes immediately after the experiment starts, and at intervals (25, 40, 44 and 70 minutes) of 15 minutes after walking.

The thermal sensation scales of the thermal sensation vote consist of 9 points, and the subjects are asked to fill in their personal information and to proffer how they are feeling following to the index on the 9-point thermal sensation scales (−4 (very cold), −3 (cold), −2 (cool), −1 (slightly cool), 0 (neutral), 1 (slightly warm), 2 (warm or slightly hot), 3 (hot), and 4 (very hot)) through a user interface provided with a touch panel or an automatic input device. The data collected from the residents may be recorded by the age-specific thermal sensation vote surveying module 20.

The experiment starts in the case where the rectal temperature is stable during at least 30 minutes, without being decreased by 37.5° C. or less. In the case where the rectal temperature is above 39.2° C., the heart rate reaches the level of 90% of the maximum heart rate, or the resident wants to stop it, the experiment can be stopped.

In this instance, age-specific theorical human heat production calculated by the human information on the subject can be considered to simulate or calculate the perceived temperature according to age (young group and elderly group).

Under the exercise loading conditions in which the young group works at the speed of 4 km h⁻¹, while the elderly group works at the speed of 2.3 km h⁻¹, it is possible to simulate or calculate the perceived temperature according to age (young group and elderly group) by use of the Klima-Michel model under the first environmental condition which is set by the temperature of 30° C., the relative humidity of 70%, and the wind speed of up to 0.3 ms⁻¹, and the second environmental conditions set by the temperature of 35° C., the relative humidity of 70%, and the wind speed of up to 0.3 ms⁻¹. The perceived temperatures of the young group simulated under each environmental condition and each exercise loading condition are 35° C. and 44° C., respectively, while the perceived temperatures of the elderly group are 32° C. and 43° C., respectively.

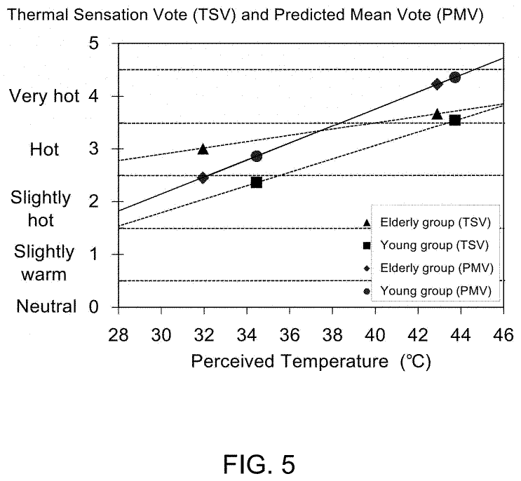

FIG. 5 is a graph illustrating a relation between the thermal sensation vote (TSV) and the predicted mean vote relative to variations in perceived temperature (PT) according to age (young group and elderly group).

The linear regression model of the age-specific thermal sensation vote (TSV) relative to variations in the age-specific perceived temperature can be calculated from FIG. 5, and the linear regression model of the thermal sensation vote (TSV) predicted from the young group and the elderly group can be calculated by Equations 1 and 2 below, in which the young group uses Equation 1, while the elderly group uses Equation 2.

TSV=0.13×PT−2.03 Equation 1

TSV=0.06×PT+1.06 Equation 2

The above Equations 1 and 2 are reflected by the values calculated from the linear regression model which is obtained from the subjects living in a certain area. The Equations 1 and 2 have a form of linear equation as an equation for calculating the linear regression model of the thermal sensation vote (TSV) predicted from the young group and the elderly group, and can be adjusted depending upon the area to be tested.

It will be understood from FIG. 5 that the relation between the perceived temperature (PT) and the thermal sensation vote (TSV) can be obtained from the age-specific thermal sensation vote and the age-specific perceived temperature according to the environmental conditions which are derived from the analysis, and also the predicted mean vote calculated from the perceived temperature model can be compared with the thermal sensation vote.

The step S500 of setting the thermal comfort scale of the age-specific perceived temperature of the residents is a step of setting the perceived temperature scale to the thermal sensation vote according to age (young group and elderly group) of residents living in a certain area or the thermal stress intensity on the basis of Equations 1 and 2 which are derived from the step S400 of predicting the age-specific thermal sensation vote in FIG. 5.

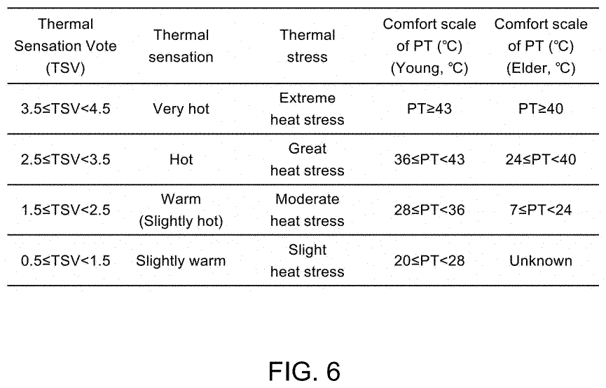

FIG. 6 is a view illustrating the danger standards (thermal comfort scale) of the perceived temperature for the young group and the elderly group, who are living in a certain area, to thermal sensation vote (thermal stress intensity) based on the thermal stress experiment according to one embodiment of the present invention.

As illustrated in FIG. 6, the thermal comfort scale of the perceived temperature for the young group living in a certain area shows very hot (43° C. or more), hot (36 to 43° C.) and warm (28 to 36° C.). The thermal comfort scale of the perceived temperature for the elderly group living in a certain area shows very hot (40° C. or more) and hot (24 to 40° C.)

It would be apparent that the scales for setting the thermal comfort scale of the perceived temperature for the subjects living in a certain area which are not obtained from two environmental conditions can be obtained from the linear regression model, but can be obtained from the experiment process which is applied by the configuration module in FIG. 1 and the steps in FIG. 2 through the addition of the experiment groups and the experimental conditions, for the purpose of more accurate setting.

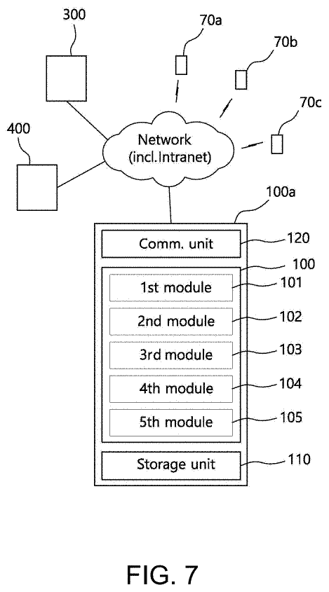

FIG. 7 is a block diagram illustrating an apparatus for setting a thermal comfort scale of a perceived temperature for residents living in a certain area according to another embodiment of the present invention.

Referring to FIG. 7, the apparatus 100a (hereinafter referred to as a thermal danger standard setting apparatus) for setting the thermal comfort scale of the age-specific perceived temperature of residents on the basis of an experiment exposed to thermal stress environment of an artificial climate chamber according to this embodiment may be realized by a computing device including a control unit 100, a storage unit 110 and a communication unit 120, and may be connected to a first body signal detecting sensor 70a, a second body signal detecting sensor 70b, a third body signal detecting sensor 70c, a first user interface 300 and a second user interface 400 via a wire and/or wireless network including Intranet. In a broad sense, the first body signal detecting sensor 70a, the second body signal detecting sensor 70b, the third body signal detecting sensor 70c, the first user interface 300 and the second user interface 400 may be provided in the thermal danger standard setting apparatus.

The first body signal detecting sensor 70a (hereinafter referred to as a first sensor) is to measure a skin temperature of the subject. The first sensor 70a may include a contact sensor which is put on a wrist, a forearm, an ankle, or an ear of the subject to make in contact with the skin of the subject, or a noncontact sensor, such as a thermal imaging camera. A signal outputted from the first sensor 70a is sent to the control unit 100.

The second body signal detecting sensor 70b (hereinafter referred to as a second sensor) includes a sensor for detecting a rectal temperature of the subject which is inserted into a rectum of the subject. The second sensor 70b is inserted into the rectum of the subject to send information on the temperature detected via the wireless communication to the control unit 100 via the communication unit 120.

The third body signal detecting sensor 70c (hereinafter referred to as a third sensor) is to measure a heart rate of the subject. The third sensor 70c may include a photo sensitive sensor or a pulse sensor which is put on the wrist of the subject in the form of a wristwatch or band. The information on the heart rate detected by the third sensor 70c is sent to the control unit 100 via the communication unit 120.

The first user interface 300 is used to set the experimental conditions. The first user interface 300 receives the information, which is directly inputted by the user, on the experiment time, the experiment location, the selection of the experiment group which is classified into the young group and the elderly group, the experiment hour for observing the progress of the experiment process, the information on the subject's body belonging to the experiment group, the heat insulating value of clothing, the environmental condition and the exercise loading condition, in advance or real time. The inputted information is stored in the storage unit or the database.

The second user interface 400 is used to survey the age-specific thermal sensation vote of the subjects. The second user interface 400 may be a touch screen including a touch panel. In this instance, the subject can input the value for the thermal sensation vote in real time by touching the touch screen during the experiment process. Also, the second user interface 400 may include a loudspeaker and a microphone. The loudspeaker outputs preset guide speech for the thermal sensation vote, and the microphone installed adjacent to the subject is inputted by an answer from the subject or a selected number according to the guide speech to send the answer or the selected number to the control unit.

The control unit 100 includes a first module 101, a second module 102, a third module 103, a fourth module 104 and a fifth module 105.

The first module 101 controls the operation of the first user interface 300 and the second user interface 400, and stores the information inputted from the first user interface 300 and the second user interface 400 in the storage unit 110. Also, the first module 101 is connected to the first to third sensors 70a, 70b and 70c to obtain detected data or measured data from the first to third sensors 70a, 70b and 70c. The obtained information is stored in the storage unit 110. The first module 101 can store or manage the experimental conditions, such as an experiment time, an experiment location, an experiment group, an experiment hour, information on a subject's body belonging to the experiment group, a heat insulating value of clothing, an environmental condition and an exercise loading condition.

The second module 102 is connected to the first module 101 to reflect the experimental conditions, and executes the thermal sensation vote according to the experimental conditions. The thermal sensation vote may be carried out by at least one of the first user interface 300 and the second user interface 400.

The third module 103 includes a first submodule and a second submodule. The first submodule calculates the age-specific predicted mean vote, while the second submodule calculates the age-specific perceived temperature. To this end, the third module 103 includes the Klima-Michel model to simulate the predicted mean vote and the age-specific perceived temperature through the Klima-Michel model which is reflected by the measuring factors of the experiment exposed to the thermal stress environment. The Klima-Michel model is known as an optimum model capable of allowing a human to evaluate the thermal environmental conditions.

The fourth module 104 predicts the linear regression model of the age-specific thermal sensation vote according to the variations in age-specific perceived temperature which is simulated by the third module 103. To this end, the fourth module 104 includes the linear regression model, and calculates the average of the variations in perceived temperature based on the information obtained from the survey results of the thermal sensation vote.

The fifth module 105 determines the perceived temperature scale to the age-specific thermal stress intensity of the residents living in a certain area on the results of the linear regression model which is derived by the fourth module. In this instance, the fifth module 105 can use the calculating formula of the linear regression model of the linear equation type to determine the thermal comfort scale of the age-specific perceived temperature of the residents living in a certain area.

With the thermal danger standard setting apparatus capable of performing the above processes by the Klima-Michel model according to this embodiment, the thermal sensation vote of the human which is a kind of sensibility reaction complicatedly combined with physiological and psychological factors can be quantitatively set as the thermal comfort state which is felt by the residents living in a certain area, under experiment environments.

The communication unit 120 is connected to the first body signal detecting sensor 70a, the second body signal detecting sensor 70b, the third body signal detecting sensor 70c, the first user interface 300 and the second user interface 400 via the wire and/or wireless network including Intranet to send or receive signals and data to or from the sensors and interfaces. The communication unit 120 may include a sub-communication system for sending or receiving signals and data to or from the other within a network according to at least one protocol.

In the thermal danger standard setting apparatus according to this embodiment, the first module 101 corresponds to the experimental condition setting module 10 in FIG. 1, the second module 102 corresponds to the age-specific thermal sensation vote surveying module 20 in FIG. 1, the third module 103 corresponds to the perceived temperature simulating (calculating) module 30 in FIG. 1, the fourth module 104 corresponds to the thermal sensation vote predicting module 40 in FIG. 1, and the fifth module 105 corresponds to the module 50 for setting the thermal comfort scale of the age-specific perceived temperature in FIG. 1.

With the above configuration of the invention, it is possible to conveniently set the thermal comport scale of the age-specific perceived temperature of the residents living in a certain area, based on the thermal stress experiment carried out in the artificial climate chamber.

Also, it is possible to provide a standard model of the perceived temperature suitable for the residents living in a certain area by setting the thermal comfort scale of the perceived temperature according to the thermal sensation vote by age (young group and elderly group) and the exposed thermal stress intensity. Based on the standard model of the perceived temperature model, a warning against the thermal stress can be issued to the residents living in the area of interest, thereby preventing a natural disaster from occurring in the elderly group of the residents due to the excessive thermal stress.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A method for setting a thermal comfort scale of an age-specific perceived temperature of residents living in a certain area based on an experiment exposed to thermal stress environment in an artificial climate chamber, the method comprising:
a step of setting an experimental condition of the experiment exposed to thermal stress environment;
a step of surveying an age-specific thermal sensation vote according to the experimental condition of the experiment exposed to thermal stress environment;
a step of simulating a predicted mean vote and an age-specific perceived temperature by use of a Klima-Michel model according to measuring elements of the experiment exposed to thermal stress environment;
a step of predicting an age-specific thermal sensation vote according to variations in perceived temperature on the basis of the survey results of the age-specific thermal sensation vote according to measuring factors of the environment exposed to the age-specific thermal stress environments and the age-specific perceived temperature; and
a step of setting a danger standard or comfort scale of the age-specific perceived temperature of the residents living in a certain.

2. The method for setting the thermal comfort scale of the age-specific perceived temperature according to claim 1, wherein the experimental condition includes an experiment time, an experiment location, an experiment group, an experiment hour, information on a subject's body belonging to the experiment group, a heat insulating value of clothing, an environmental condition and an exercise loading condition.

3. The method for setting the thermal comfort scale of the age-specific perceived temperature according to claim 2, wherein the environmental condition includes a temperature, a relative humidity and a wind speed.

4. The method for setting the thermal comfort scale of the age-specific perceived temperature according to claim 1, wherein the step of predicting the age-specific thermal sensation vote calculates a linear regression model for results of the thermal sensation vote to variations in the perceived temperature, in which a young group is applied to Equation 1 below, while an elderly group is applied to Equation 2 below:
TSV=0.13×PT−2.03 (Equation 1)
TSV=0.06×PT+1.06 (Equation 2).

5. A method for setting a thermal comfort scale of an age-specific perceived temperature of regional residents based on an experiment exposed to thermal stress environment in an artificial climate chamber, the method comprising:
a step of setting an experimental condition of the experiment exposed to thermal stress environment, the experimental condition including an experiment time, an experiment location, an experiment group, an experiment hour, information on a subject's body belonging to the experiment group, a heat insulating value of clothing, an environmental condition and an exercise loading condition;
a step of obtaining survey results from an age-specific thermal sensation vote according to the experimental condition of the experiment exposed to thermal stress environment;
a step of simulating an age-specific predicted mean vote and an age-specific perceived temperature by use of a Klima-Michel model according to measuring elements of the experiment exposed to thermal stress environment;
a step of predicting an age-specific thermal sensation vote according to variations in perceived temperature on the basis of the survey results of the age-specific thermal sensation vote, the age-specific simulated predicted mean vote and the age-specific simulated perceived temperature; and
a step of setting a danger standard or comfort scale of the age-specific perceived temperature of the regional residents, to which a subject belongs, on the basis of the predicted value of the age-specific thermal sensation vote.

6. The method for setting the thermal comfort scale of the age-specific perceived temperature according to claim 5, wherein the step of predicting the age-specific thermal sensation vote includes a step of predicting a linear regression model of the age-specific thermal sensation vote to variations in the simulated age-specific perceived temperature.

7. The method for setting the thermal comfort scale of the age-specific perceived temperature according to claim 5, wherein the step of setting the comfort scale uses a calculating formula of a linear regression model of a linear equation type to determine the thermal comfort scale of the age-specific perceived temperature of the residents living in a certain area.

8. An apparatus for setting a thermal comfort scale of an age-specific perceived temperature of regional residents based on an experiment exposed to thermal stress environment in an artificial climate chamber, the apparatus comprising:
a first module for setting an experimental condition of the experiment exposed to thermal stress environment, the experimental condition including an experiment time, an experiment location, an experiment group, an experiment hour, information on a subject's body belonging to the experiment group, a heat insulating value of clothing, an environmental condition and an exercise loading condition;
a second module for obtaining survey results from an age-specific thermal sensation vote according to the experimental condition of the experiment exposed to thermal stress environment;
a third module for simulating an age-specific predicted mean vote and an age-specific perceived temperature by use of a Klima-Michel model according to measuring elements of the experiment exposed to thermal stress environment;
a fourth module for predicting an age-specific thermal sensation vote according to variations in perceived temperature on the basis of the survey results of the age-specific thermal sensation vote, the age-specific simulated predicted mean vote and the age-specific simulated perceived temperature; and
a fifth module for setting a danger standard or comfort scale of the age-specific perceived temperature of the regional residents, to which a subject belongs, on the basis of the predicted value of the age-specific thermal sensation vote.

9. The apparatus for setting the thermal comfort scale of the age-specific perceived temperature according to claim 8, wherein the fourth module predicts a linear regression model of the age-specific thermal sensation vote to variations in the simulated age-specific perceived temperature.

10. The apparatus for setting the thermal comfort scale of the age-specific perceived temperature according to claim 9, wherein the fifth module uses a calculating formula of a linear regression model of a linear equation type to determine the thermal comfort scale of the age-specific perceived temperature of the residents living in a certain area.
